(19) United States
(12) Patent Application Publication
(10) Pub. No.: US 2026/0150732 A1
(43) Pub. Date: May 28, 2026

(54) SEMICONDUCTOR DEVICE

(71) Applicant: Mitsubishi Electric Corporation, Tokyo (JP)

(72) Inventors: Hitoshi MAKISHIMA, Tokyo (JP); Toshiya TADAKUMA, Tokyo (JP)

(73) Assignee: Mitsubishi Electric Corporation, Tokyo (JP)

(21) Appl. No.: 19/309,475

(22) Filed: Aug. 25, 2025

(30) Foreign Application Priority Data
Nov. 25, 2024 (JP) 2024-204449

(51) Int. Cl. H01L 23/538; H01L 23/40; H01L 23/473; H01L 23/498; H01L 25/10

(52) U.S. Cl. CPC H10W 70/65; H10W 70/611; H10W 90/00; H10W 90/401; H10W 90/701; H10W 40/47; H10W 40/611

(57) ABSTRACT

A semiconductor device includes: a base plate; a semiconductor module including a control terminal and provided to an upper surface of the base plate; a control substrate which is provided on an upper side of the semiconductor module and the control terminal is connected to; and a terminal guide including a passing hole through which the control terminal passes, a guide upper surface provided to face a lower surface of the control substrate, at least a part of the guide upper surface having contact with the lower surface of the control substrate, a guide lower surface, at least a part of which is disposed in a position of the upper surface of the semiconductor module or below the position of the upper surface of the semiconductor module, and a body part connecting the guide upper surface and the guide lower surface.

### BACKGROUND

### Technical Field

The present disclosure relates to a semiconductor device including a terminal connected to a control substrate.

### Description of the Background Art

Disclosed in a conventional technique is a semiconductor device in which a terminal housing part is formed in a position in which a control terminal for a control signal is disposed (for example, Japanese Patent Application Laid-Open No. 2006-165499).

### SUMMARY

However, the conventional terminal housing part has a problem that a distance from a semiconductor module to a control substrate cannot be determined; thus, there is a possibility that a sufficient insulating space distance cannot be ensured.

The present disclosure is therefore has been made to solve problems as described above, and it is an object to provide a semiconductor device capable of ensuring a sufficient insulating space distance.

A semiconductor device according to the present disclosure includes a base plate, a semiconductor module, a control substrate, and a terminal guide.

The semiconductor module includes a control terminal, and is provided to an upper surface of the base plate.

The control substrate is provided on an upper side of the semiconductor module, and the control terminal is connected.

The terminal guide includes a passing hole, a guide upper surface, a guide lower surface, and a body part.

The control terminal passes through the passing hole.

The guide upper surface is provided to face a lower surface of the control substrate, and at least a part of the guide upper surface has contact with the lower surface of the control substrate.

At least a part of the guide lower surface is disposed in a position of an upper surface of the semiconductor module or below the position of the upper surface of the semiconductor module.

The body part connects the guide upper surface and the guide lower surface.

According to the semiconductor device of the present disclosure, a sufficient insulating space distance can be ensured.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a perspective view of a semiconductor device according to an embodiment 1 in the present disclosure.

FIG. 2 is a perspective view of the semiconductor device according to the embodiment 1 in the present disclosure.

FIG. 3 is a perspective view of the semiconductor device according to the embodiment 1 in the present disclosure.

FIG. 4 is a side view of the semiconductor device according to the embodiment 1 in the present disclosure.

FIG. 5 is a perspective view of a terminal guide according to the embodiment 1 in the present disclosure.

FIG. 6 is a side view of the terminal guide according to the embodiment 1 in the present disclosure.

FIG. 7 is a top view of the terminal guide according to the embodiment 1 in the present disclosure.

FIG. 8 is a cross-sectional view of the terminal guide according to the embodiment 1 in the present disclosure.

FIG. 9 is a top view of a terminal guide according to an embodiment 2 in the present disclosure.

FIG. 10 is a side view of a semiconductor device according to an embodiment 3 in the present disclosure.

FIG. 11 is a perspective view of a semiconductor device according to an embodiment 4 in the present disclosure.

FIG. 12 is a perspective view of a semiconductor device according to an embodiment 5 in the present disclosure.

FIG. 13 is a side view of the semiconductor device according to the embodiment 5 in the present disclosure.

FIG. 14 is a perspective view of a semiconductor device according to an embodiment 6 in the present disclosure.

FIG. 15 is a side view of the semiconductor device according to the embodiment 6 in the present disclosure.

### DESCRIPTION OF THE PREFERRED EMBODIMENTS

Embodiments of the present disclosure are described with reference to the appended diagrams hereinafter. Since the diagrams are schematically illustrated, a mutual relationship of sizes and positions respectively illustrated in the different diagrams is not necessarily limited thereto, but may be appropriately changed. In the description hereinafter, the same reference numerals will be assigned to the similar constituent elements, and the constituent elements having the same reference numeral have the similar name and function. Accordingly, the detailed description on them may be omitted in some cases.

### Embodiment 1

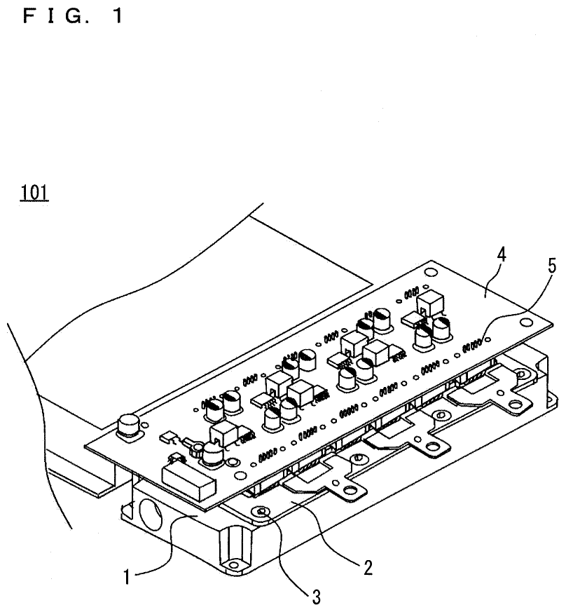

A semiconductor device 101 according to an embodiment 1 is described using FIG. 1 to FIG. 8. FIG. 1 is a perspective view of the semiconductor device 101 according to the embodiment 1. As illustrated in FIG. 1, the semiconductor device 101 according to the present embodiment includes a water cooling jacket 1, a base plate 2, a screw 3, and a control substrate 4.

The base plate 2 is provided to an upper surface of the water cooling jacket 1. The control substrate 4 is provided on an upper side of the base plate 2 (without having contact with the base plate 2). A side on which the control substrate 4 is provided is an upper side, and a side on which the water cooling jacket 1 is provided is a lower side based on the base plate 2. A surface on the upper side is an upper surface, and a surface on the lower side is a lower surface. The upper side, the lower side, the upper surface, and the lower surface are defined regardless of a gravity direction at a time of locating the semiconductor device 101. A direction passing through the upper surface and the lower surface is a height direction. A surface other than the upper surface and the lower surface is a side surface. The same applies to the description hereinafter.

The base plate 2 is fastened to the water cooling jacket 1 by the screw 3. The control substrate 4 includes a through hole 5. A control terminal described hereinafter is inserted into the through hole 5. The plurality of through holes 5 are provided, for example. The control terminal is inserted into each of the plurality of through holes 5.

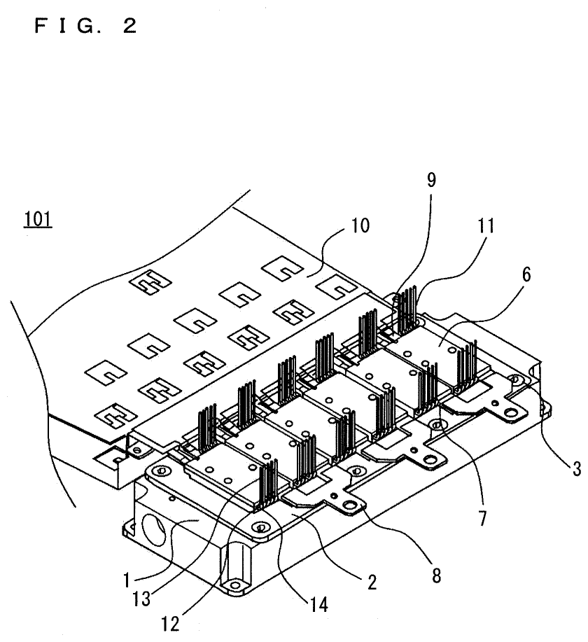

FIG. 2 is a perspective view of the semiconductor device 101 according to the embodiment 1. In FIG. 2, description of the control substrate 4 and a terminal guide described hereinafter is omitted. As illustrated in FIG. 2, the semiconductor device 101 includes a semiconductor module 6, a DC-input main terminal part 9, and a DC bus-bar 10.

The semiconductor module 6 is provided on an upper surface of the base plate 2. The semiconductor module 6 includes a control terminal 11, an AC-output main terminal part 7, and an AC bus-bar 8. The control terminal 11 passes through the through hole 5 of the control substrate 4. The control terminal 11 is electrically connected to the control substrate 4. The control terminal 11 is bonded to the control substrate 4 by soldering, for example. The semiconductor module 6 is sealed by resin, for example, and the control terminal 11 is partially exposed from the resin. The semiconductor module 6 is a power module, for example. The plurality of semiconductor modules 6 are provided, for example. Only one semiconductor module 6 may be provided.

The control terminal 11 includes a protrusion part 12, a standing part 13, and a bending part 14. The protrusion part 12 protrudes in a direction parallel to the upper surface of the base plate 2. The protrusion part 12 protrudes in a direction parallel to a lower surface of the control substrate 4.

The standing part 13 stands on an upper side of the base plate 2. The standing part 13 is provided in a direction perpendicular to the upper surface of the base plate 2, for example. The standing part 13 is provided in a direction perpendicular to the lower surface of the control substrate 4, for example. The standing part 13 passes through the through hole 5 of the control substrate 4. The standing part 13 is electrically connected to the control substrate 4.

The bending part 14 connects the protrusion part 12 and the standing part 13. The control terminal 11 is bended at the bending part 14. The protrusion part 12, the standing part 13, and the bending part 14 are integrally formed, for example.

The AC-output main terminal part 7 is partially exposed from resin sealing the semiconductor module 6. The AC-output main terminal part 7 is electrically connected to the AC bus-bar 8. The DC-input main terminal part 9 is partially exposed from the resin sealing the semiconductor module 6. The DC-input main terminal part 9 is electrically connected to the DC bus-bar 10.

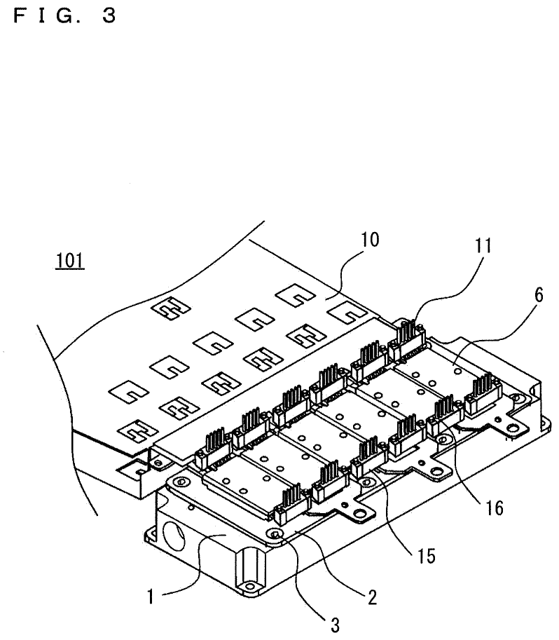

FIG. 3 is a perspective view of the semiconductor device 101 according to the embodiment 1. In FIG. 3, description of the control substrate 4 is omitted. As illustrated in FIG. 3, the semiconductor device 101 according to the present embodiment includes a terminal guide 15.

The terminal guide 15 covers the control terminal 11. The control terminal 11 may be partially exposed from the terminal guide 15. The terminal guide 15 includes a passing hole 16 through which the control terminal 11 passes. The terminal guide 15 is provided to cover the plurality of control terminals 11 protruding from one side surface of the semiconductor module 6. The semiconductor module 6 is provided to cover each of the plurality of control terminals 11. The plurality of terminal guides 15 are provided to cover the control terminals 11 protruding from different side surfaces of the semiconductor module 6, respectively. That is to say, the terminal guide 15 is provided to each side surface of the semiconductor module 6. The terminal guide 15 is provided to each of the plurality of semiconductor modules 6. The terminal guide 15 needs not cover the whole control terminal 11, but may cover only a part thereof.

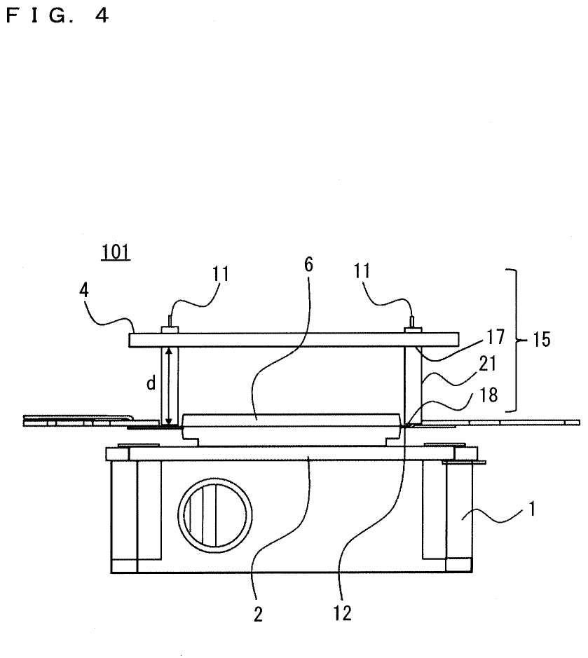

FIG. 4 is a side view of the semiconductor device 101 according to the embodiment 1. As illustrated in FIG. 4, the terminal guide 15 is provided between the base plate 2 and the control substrate 4. The terminal guide 15 determines a distance from the protrusion part 12 of the control terminal 11 to the lower surface of the control substrate 4. The terminal guide 15 includes a guide upper surface 17, a guide lower surface 18, and a body part 21.

The guide upper surface 17 is provided to face the lower surface of the control substrate 4. At least a part of the guide upper surface 17 is provided to have contact with the lower surface of the control substrate 4. The guide lower surface 18 is provided to face the upper surface of the base plate 2. At least a part of the guide lower surface 18 is disposed in a position of an upper surface of the semiconductor module 6 or below the position of the upper surface of the semiconductor module 6. The body part 21 connects the guide upper surface 17 and the guide lower surface 18.

As illustrated in FIG. 4, at least a part of the guide lower surface 18 of the semiconductor device 101 according to the present embodiment is provided to have contact with the protrusion part 12 of the control terminal 11. A length from a part of the guide lower surface 18 having contact with the protrusion part 12 of the control terminal 11 to a part of the guide upper surface 17 having contact with the lower surface of the control substrate 4 is a distance from the protrusion part 12 to the lower surface of the control substrate 4. That is to say, the terminal guide 15 can determine the distance from the protrusion part 12 to the lower surface of the control substrate 4. Since the distance from the protrusion part 12 to the lower surface of the control substrate 4 is determined, that is to say, the distance from the protrusion part 12 to the lower surface of the control substrate 4 is ensured, a sufficient insulating space distance can be ensured.

A length d shown by an arrow in FIG. 4 has the same dimension as the distance from the protrusion part 12 to the lower surface of the control substrate 4 which is a length from the part of the guide lower surface 18 having contact with the protrusion part 12 to the part of the guide upper surface 17 having contact with the control substrate 4 and is a height of the control substrate 4 based on the protrusion part 12. That is to say, the terminal guide 15 includes a part having the same dimension as the distance from the protrusion part 12 to the lower surface of the control substrate 4.

Since the guide lower surface 18 has contact with the protrusion part 12, the terminal guide 15 determines the height of the control substrate 4 based on the protrusion part 12. Since the guide lower surface 18 has contact with the protrusion part 12, a necessary insulating space distance from the protrusion part 12 to the lower surface of the control substrate 4 can be ensured more accurately.

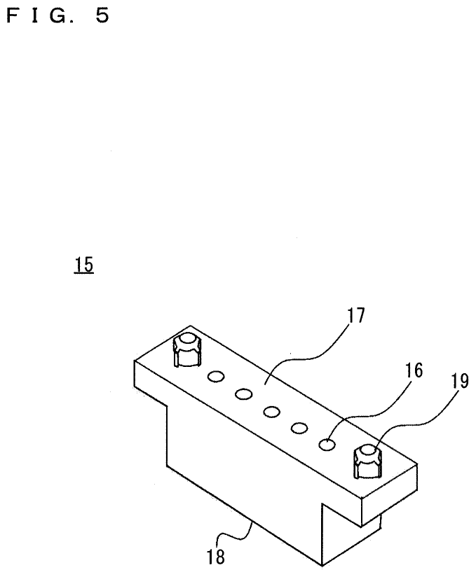

FIG. 5 is a perspective view of the terminal guide 15 according to the embodiment 1. As illustrated in FIG. 5, the terminal guide 15 includes the plurality of passing holes 16, for example. As illustrated in FIG. 3, the plurality of control terminals 11 pass through the plurality of passing holes 16, respectively. The terminal guide 15 may include only one passing hole 16. The plurality of control terminals 11 may be passed through one passing hole 16. As illustrated in FIG. 5, the terminal guide 15 includes a fixing part 19.

The terminal guide 15 sandwiches the control substrate 4 between the guide upper surface 17 and the fixing part 19, thereby being mutually fixed to the control substrate 4. A method of fixing the terminal guide 15 is not limited thereto described above.

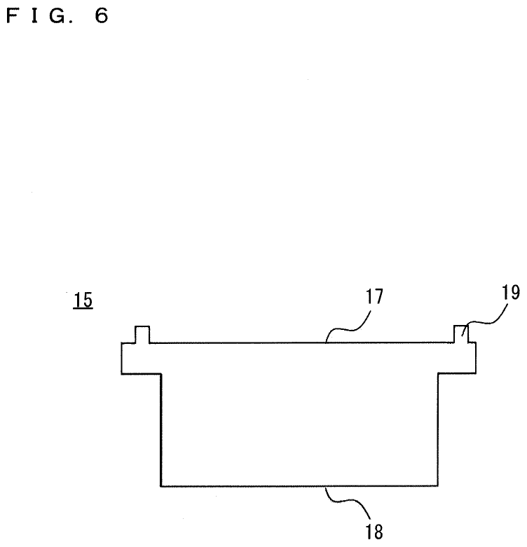

FIG. 6 is a side view of the terminal guide 15 according to the embodiment 1. As illustrated in FIG. 6, a position in the terminal guide 15 facing the fixing part 19 extends, for example. The terminal guide 15 includes a side surface with a T-like shape, for example. The position in the terminal guide 15 facing the fixing part 19 may not extend. The shape of the side surface of the terminal guide 15 may be a rectangle, for example.

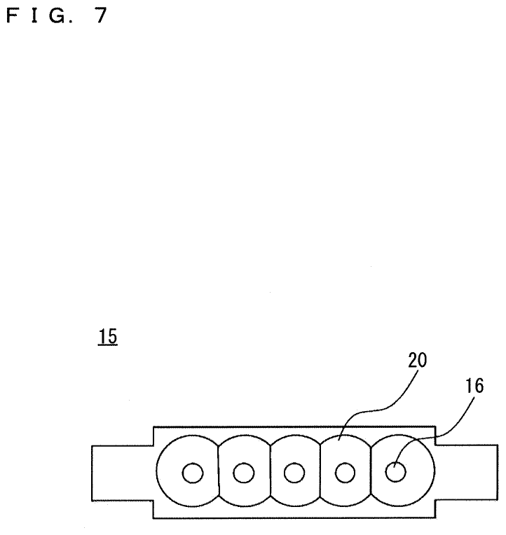

FIG. 7 is a top view of the terminal guide 15 according to the embodiment 1. As illustrated in FIG. 7, the terminal guide 15 includes an upper surface concave part 20 around the passing hole 16, for example. Since the terminal guide 15 includes the upper surface concave part 20, a terminal is easily inserted into the terminal guide 15.

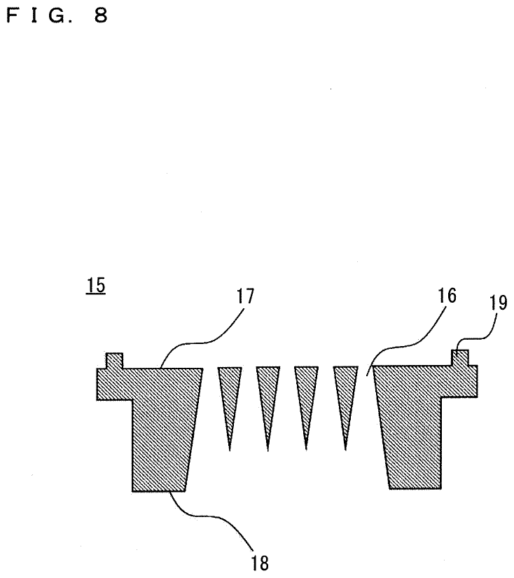

FIG. 8 is a cross-sectional view of the terminal guide 15 according to the embodiment 1. As illustrated in FIG. 8, the passing hole 16 of the terminal guide 15 has a cone-like shape, for example. The passing hole 16 has a shape that a diameter on a side of the base plate 2 as the lower side is larger than that on a side of the control substrate 4 as the upper side. The passing hole 16 has a shape that a diameter gradually increases from the side of the control substrate 4 as the upper side toward the side of the base plate 2 as the lower side, for example. Since the passing hole 16 has shape that the diameter on the upper side is small and the diameter on the lower side is large, the plurality of control terminals 11 are easily inserted into the terminal guide 15.

The semiconductor device 101 according to the present embodiment includes: the base plate; the semiconductor module including the control terminal and provided to the upper surface of the base plate; the control substrate which is provided on the upper side of the semiconductor module (above the semiconductor module) and the control terminal is connected to; and the terminal guide including the passing hole through which the control terminal passes, the guide upper surface provided to face the lower surface of the control substrate, at least a part of the guide upper surface having contact with the lower surface of the control substrate, the guide lower surface, at least a part of which is disposed in the position of the upper surface of the semiconductor module or below the position of the upper surface of the semiconductor module, and the body part connecting the guide upper surface and the guide lower surface. Accordingly, the sufficient insulating space distance can be ensured.

### Embodiment 2

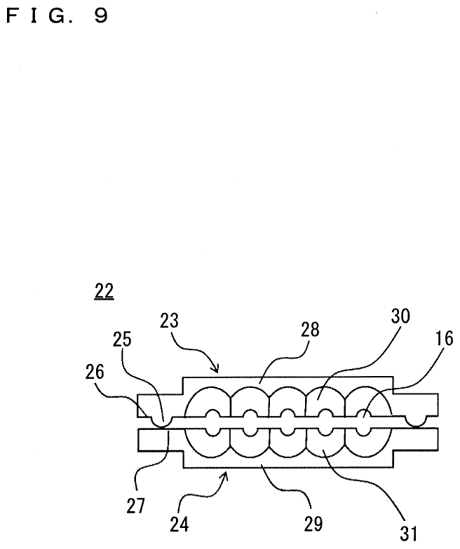

A terminal guide 22 according to an embodiment 2 is described using FIG. 9. The description of a configuration similar to that in the embodiment 1 is omitted. In FIG. 9, the same reference numerals as those in FIG. 1 to FIG. 8 indicate the same or corresponding part. The terminal guide 22 according to the present embodiment is different from the terminal guide 15 according to the embodiment 1 in that the terminal guide 22 is divided into a plurality of components. Points different from those in the embodiment 1 are mainly described hereinafter.

FIG. 9 is a top view of the terminal guide 22 according to the embodiment 2. The terminal guide 22 includes a guide first component 23 and a guide second component 24. The terminal guide 22 is provided to be divided into the guide first component 23 and the guide second component 24. The terminal guide 22 is provided to be divided in a direction parallel to the control terminal 11. The terminal guide 22 is provided to be divided at a surface including the passing hole 16. The terminal guide 22 is provided to be divided in a direction parallel to a height direction.

The guide first component 23 and the guide second component 24 are fixed while sandwiching the control terminal 11. The control terminal 11 is provided to be sandwiched between the guide first component 23 and the guide second component 24 while passing through the passing hole 16.

The guide first component 23 includes a guide inner surface 26. The guide second component 24 includes a guide inner surface 27. The terminal guide 22 includes a locking convex part 25 and a locking concave part not shown in the diagrams but locked to the locking convex part 25.

The guide first component 23 includes the locking convex part 25. The locking convex part 25 is provided to the guide inner surface 26. The guide first component 23 includes the plurality of locking convex parts 25, for example. The guide first component 23 includes two locking convex parts 25, for example. The guide first component 23 may include three or more locking convex parts 25. The guide first component 23 may include only one locking convex part 25. The guide first component 23 may not include the locking convex part 25. The locking convex part 25 may be provided to the guide inner surface 27.

The guide second component 24 includes the locking concave part. The locking concave part is provided to the guide inner surface 27. The guide second component 24 includes the plurality of locking concave parts, for example. The guide second component 24 includes two locking concave parts, for example. The guide second component 24 may include three or more locking concave parts. The guide second component 24 may include only one locking concave part. The guide second component 24 may not include the locking concave part. The locking convex part may be provided to the guide inner surface 26. For example, each of the guide first component 23 and the guide second component 24 may include one locking convex part 25 and one locking concave part.

The guide first component 23 includes a guide upper surface 28 and a guide lower surface not shown in the diagrams. The guide second component 24 includes a guide upper surface 29 and a guide lower surface not shown in the diagrams. The guide upper surface is provided to face the lower surface of the control substrate 4. In the manner similar to the terminal guide 15 according to the embodiment 1, at least a part of a guide upper surface of the terminal guide 22 has contact with the lower surface of the control substrate 4. That is to say, one of or both the guide upper surface 28 included in the guide first component 23 and the guide upper surface 29 included in the guide second component 24 may be provided to have contact with the lower surface of the control substrate 4. A part of the guide upper surface 28 or a part of the guide upper surface 29 may be provided to have contact with the lower surface of the control substrate 4.

The guide lower surface of the terminal guide 22 is provided to face the upper surface of the base plate 2. In the manner similar to the terminal guide 15 according to the embodiment 1, at least a part of the guide lower surface of the terminal guide 22 is disposed in a position of the upper surface of the semiconductor module 6 or below the position of the upper surface of the semiconductor module 6. That is to say, one of or both the guide lower surface included in the guide first component 23 and the guide lower surface included in the guide second component 24 may be provided to have contact with the lower surface of the control substrate 4. A part of the guide lower surface included in the guide first component 23 or a part of the guide lower surface included in the guide second component 24 may be located in a position of the upper surface of the semiconductor module 6 or below the position of the upper surface of the semiconductor module 6. The guide first component 23 includes an upper surface concave part 30. The guide second component 24 includes an upper surface concave part 31. At least a part of the guide lower surface is provided to have contact with the protrusion part 12 of the control terminal 11.

The terminal guide 22 is divided in a direction parallel to the control terminal 11 at a surface including the passing hole 16. Accordingly, the terminal guide 22 can be attached to the control terminal 11 while sandwiching the control terminal 11, and even when a positional tolerance of the control terminal 11 is large, displacement between the control terminal 11 and the control substrate 4 can be reduced.

### Embodiment 3

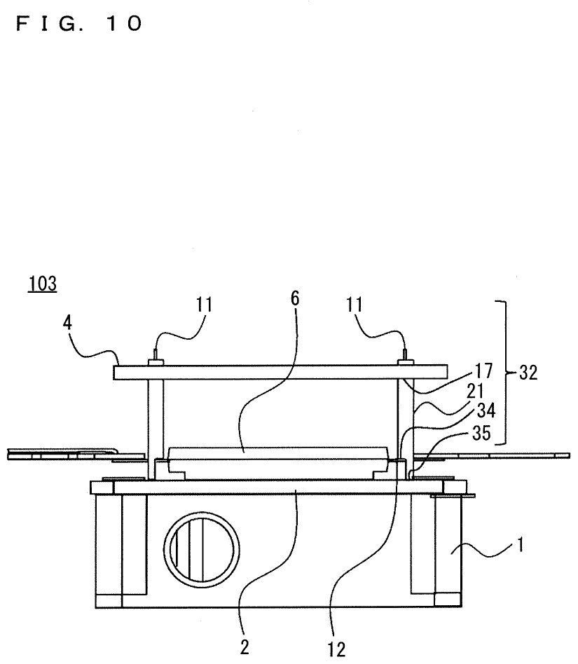

A semiconductor device 103 according to an embodiment 3 is described using FIG. 10. The description of a configuration similar to that in the embodiment 1 is omitted. In FIG. 10, the same reference numerals as those in FIG. 1 to FIG. 9 indicate the same or corresponding part. The semiconductor device 103 according to the present embodiment is different from the semiconductor device 101 according to the embodiment 1 in that a guide lower surface 33 of the terminal guide 32 has contact with the base plate 2. Points different from those in the embodiment 1 are mainly described hereinafter.

FIG. 10 is a side view of the semiconductor device 103 according to the embodiment 3. The semiconductor device 103 includes the terminal guide 32. The terminal guide 32 includes the guide upper surface 17 and the guide lower surface 33. The guide upper surface 17 is provided to face the lower surface of the control substrate 4. At least a part of the guide upper surface 17 is provided to have contact with the lower surface of the control substrate 4.

The guide lower surface 33 is provided to face the upper surface of the base plate 2. At least a part of the guide lower surface 33 is disposed in a position of the upper surface of the semiconductor module 6 or below the position of the upper surface of the semiconductor module 6. As illustrated in FIG. 10, the guide lower surface 33 includes a first lower surface 34 and a second lower surface 35 located in positions different from each other in a height direction. That is to say, the terminal guide 32 includes a shape such as a level difference or a notch.

The first lower surface 34 is provided to have contact with the protrusion part 12 of the control terminal 11. The second lower surface 35 is provided to have contact with the upper surface of the base plate 2. Since the second lower surface 35 included in the guide lower surface 33 is provided to have contact with the base plate 2, an insulating space distance which should be ensured between the protrusion part 12 and the control substrate 4 can be indirectly ensured.

Since the first lower surface 34 included in the guide lower surface 33 is provided to have contact with the protrusion part 12 and the second lower surface 35 included in the guide lower surface 33 is provided to have contact with the upper surface of the base plate 2, load applied to the protrusion part 12 by gravity on the terminal guide 32 and the control substrate 4 can be reduced while the insulating space distance which should be ensured between the protrusion part 12 and the control substrate 4 is ensured.

The first lower surface 34 may not have contact with the protrusion part 12. Also in a case where the first lower surface 34 does not have contact with the protrusion part 12, the second lower surface 35 is provided to have contact with the upper surface of the base plate 2; thus, the insulating space distance which should be ensured between the protrusion part 12 and the control substrate 4 can be indirectly ensured. Since the first lower surface 34 does not have contact with the protrusion part 12, the load by the gravity on the terminal guide 32 and the control substrate 4 is not applied to the protrusion part 12. Thus, deformation of the control terminal 11 by the load can be prevented.

The first lower surface 34 may be provided to have contact with the upper surface of the semiconductor module 6. Since the first lower surface 34 has contact with the upper surface of the semiconductor module 6, a height of the control substrate 4 can be adjusted based on the upper surface of the semiconductor module 6. Also in a case where the first lower surface 34 is provided to have contact with the upper surface of the semiconductor module 6, the distance from the protrusion part 12 to the lower surface of the control substrate 4 can be indirectly ensured. Thus, a necessary insulating space distance can be ensured.

### Embodiment 4

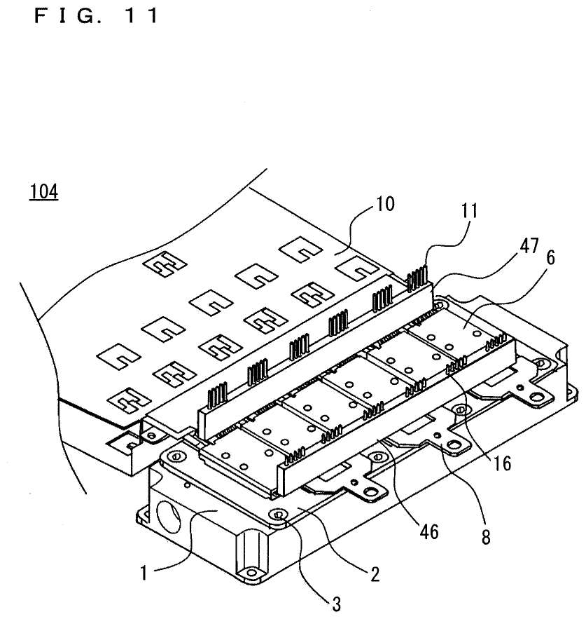

A semiconductor device 104 according to an embodiment 4 is described using FIG. 11. The description of a configuration similar to that in the embodiment 1 is omitted. In FIG. 11, the same reference numerals as those in FIG. 1 to FIG. 10 indicate the same or corresponding part. The semiconductor device 104 according to the present embodiment is different from the semiconductor device 101 according to the embodiment 1 in that terminal guides covering the control terminals 11 of the semiconductor modules 6 adjacent to each other are connected. Points different from those in the embodiment 1 are mainly described hereinafter.

FIG. 11 is a perspective view of the semiconductor device 104 according to the embodiment 4. In FIG. 11, description of the control substrate 4 is omitted. The semiconductor device 104 includes the plurality of semiconductor modules 6, a terminal guide 46 and a terminal guide 47. The terminal guide 46 and the terminal guide 47 cover the control terminals 11 protruding from the different semiconductor modules 6. The control terminals 11 protruding from the plurality of semiconductor modules 6 are passed through the passing holes 16 included in the terminal guide 46 and the terminal guide 47. The control terminal 11 is passed thorough the passing hole 16 one by one, for example. In the terminal guide 46 and the terminal guide 47, the terminal guides covering the control terminals 11 of the semiconductor modules 6 adjacent to each other in the terminal guide 15 according to the embodiment 1 are connected and integrated. The terminal guide 46 and the terminal guide 47 need not cover the whole control terminal 11, but may cover only a part thereof.

The semiconductor module 6 includes a first side surface provided on a side of the AC bus-bar 8 and a second side surface provided on a side of the DC bus-bar 10. The terminal guide 46 is provided to cover the control terminal 11 protruding from the first side surface of each of the plurality of semiconductor modules 6. The terminal guide 47 covers the control terminal 11 protruding from the second side surface of each of the plurality of semiconductor modules 6. That is to say, the terminal guide 46 and the terminal guide 47 are provided to cover the control terminal 11 protruding from the side surface provided in the same direction in the respective side surfaces of the plurality of semiconductor modules 6.

Since the terminal guide 46 and the terminal guide 47 are provided to cover the control terminal 11 protruding from the side surface provided in the same direction in the respective side surfaces of the plurality of semiconductor modules 6, the position of the control substrate 4 in the height direction can be easily determined by aligning the positions of the terminal guide 46 and the terminal guide 47, and the control substrate 4 can be easily attached to the semiconductor module 6.

The terminal guide 46 or the terminal guide 47 and the terminal guide 15 according to the embodiment 1 may be provided in combination.

### Embodiment 5

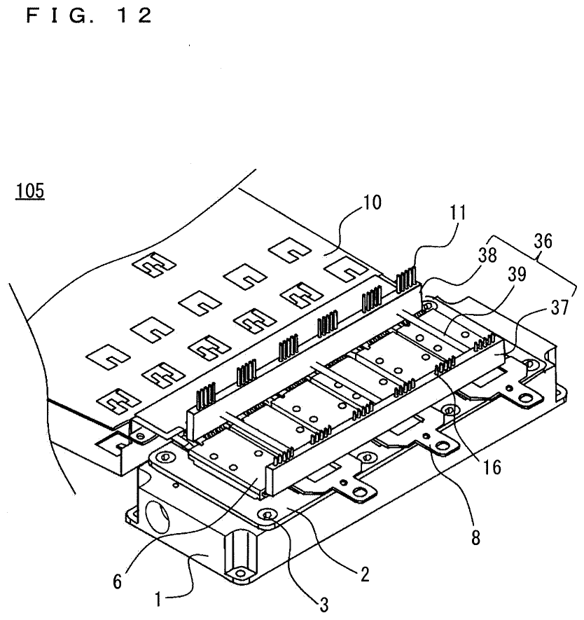

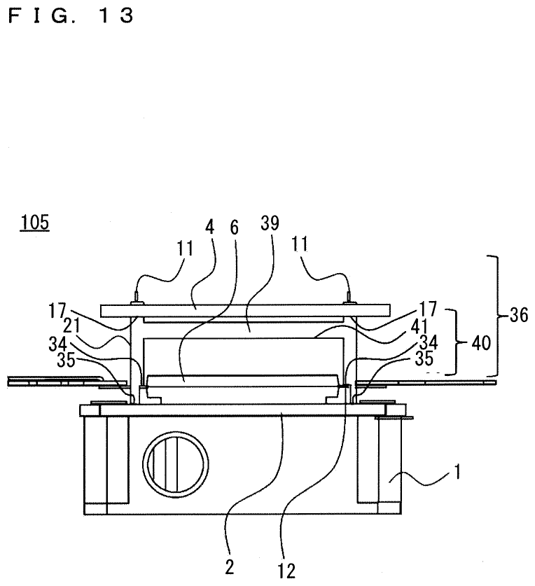

A semiconductor device 105 according to an embodiment 5 is described using FIG. 12 and FIG. 13. The description of a configuration similar to that in the embodiment 4 is omitted. In FIG. 12 and FIG. 13, the same reference numerals as those in FIG. 1 to FIG. 11 indicate the same or corresponding part. The semiconductor device 105 according to the present embodiment 5 is different from the semiconductor device 104 according to the embodiment 4 in that a relay part 39 is provided to a terminal guide 36. Points different from those in the embodiment 1 are mainly described hereinafter.

FIG. 12 is a perspective view of the semiconductor device 105 according to the embodiment 5. In FIG. 12, description of the control substrate 4 is omitted. The semiconductor device 105 includes the terminal guide 36. The terminal guide 36 includes a first terminal guide part 37, a second terminal guide part 38, and the relay part 39.

The first terminal guide part 37 corresponds to the terminal guide 46 according to the embodiment 4. That is to say, the first terminal guide part 37 covers the control terminal 11 protruding from one side surface of the semiconductor module 6. The second terminal guide part 38 corresponds to the terminal guide 47 according to the embodiment 4. That is to say, the second terminal guide part 38 covers the control terminal 11 protruding from the other side surface located on a side opposite to one side surface.

The relay part 39 connects the first terminal guide part 37 and the second terminal guide part 38. The first terminal guide part 37, the second terminal guide part 38, and the relay part 39 are integrally formed, for example. It is also applicable that the first terminal guide part 37, the second terminal guide part 38, and the relay part 39 are formed as separate bodies and connected by a screw, for example.

Since the first terminal guide part 37 and the second terminal guide part 38 are connected by the relay part 39, the control terminal 11 can be easily inserted into the first terminal guide part 37 and the second terminal guide part 38. That is to say, the control terminal 11 is easily inserted into the terminal guide 36.

FIG. 13 is a side view of the semiconductor device 105 according to the embodiment 5. As illustrated in FIG. 13, the relay part 39 is provided above the semiconductor module 6, for example. For example, the relay part 39 is provided in a position facing the upper surface of the semiconductor module 6. The relay part 39 needs not be provided in the position facing the upper surface of the semiconductor module 6, but may also be provided in a position above the semiconductor module 6 not to face the upper surface of the semiconductor module 6. That is to say, the relay part 39 may be provided above the semiconductor module 6 in front of or in back of the semiconductor module 6. The relay part 39 may not be provided above the semiconductor module 6, but may be provided below the upper surface of the semiconductor module 6. That is to say, the relay part 39 may be provided in a position overlapped with the semiconductor module 6 in front of or in back of the semiconductor module 6 in FIG. 13.

The terminal guide 36 includes a guide lower surface 40. The guide lower surface 40 includes the first lower surface 34, the second lower surface 35, and a third lower surface 41. The relay part 39 includes the third lower surface 41 as a part of the guide lower surface 40. The third lower surface 41 may be provided to have contact with the upper surface of the semiconductor module 6. Since the third lower surface 41 has contact with the upper surface of the semiconductor module 6, the height of the control substrate 4 can be adjusted based on the upper surface of the semiconductor module 6.

Also in a case where the third lower surface 41 is provided to have contact with the upper surface of the semiconductor module 6, the distance from the protrusion part 12 to the lower surface of the control substrate 4 can be indirectly ensured. Thus, a necessary insulating space distance can be ensured. Accordingly, also in a case where the first lower surface 34 and the second lower surface 35 do not have contact with any of the protrusion part 12 of the control terminal 11 and the base plate 2, the necessary insulating space distance can be ensured. When the first lower surface 34 does not have contact with the protrusion part 12, the load by the gravity on the terminal guide 36 and the control substrate 4 is not applied to the protrusion part 12. Thus, deformation of the control terminal 11 by the load can be prevented.

### Embodiment 6

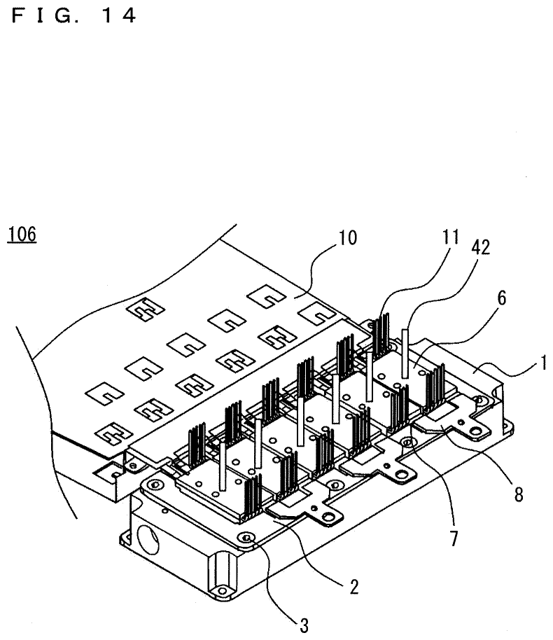

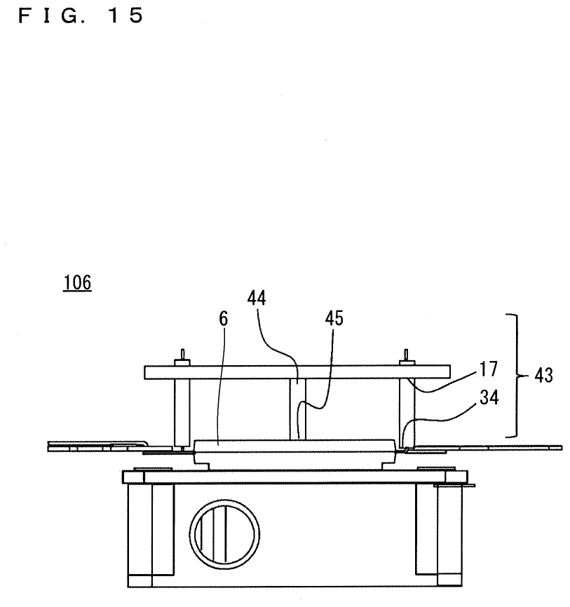

A semiconductor device 106 according to an embodiment 6 is described using FIG. 14 and FIG. 15. The description of a configuration similar to that in the embodiment 1 is omitted. In FIG. 14 and FIG. 15, the same reference numerals as those in FIG. 1 to FIG. 13 indicate the same or corresponding part. The semiconductor device 106 according to the present embodiment is different from the semiconductor device 104 according to the embodiment 4 in that a control terminal 42 is provided to the upper surface of the semiconductor module 6 and a terminal guide 43 covers the control terminal 42. Points different from those in the embodiment 1 are mainly described hereinafter.

FIG. 14 is a perspective view of the semiconductor device 106 according to the embodiment 6. In FIG. 14, description of the control substrate 4, the terminal guide 43, and the terminal guide 44 is omitted. The semiconductor device 106 includes the control terminal 42 provided to the upper surface of the semiconductor module 6. The control terminal 42 is electrically connected to the control substrate 4.

FIG. 15 is a side view of the semiconductor device 106 according to the embodiment 6. The semiconductor device 106 includes the terminal guide 43 and the terminal guide 44. The terminal guide 43 corresponds to the terminal guide 15 according to the embodiment 1. The terminal guide 44 covers the control terminal 42. The terminal guide 44 needs not cover the whole control terminal 42, but may cover only a part thereof.

The terminal guide 44 includes a guide lower surface 45. The guide lower surface 45 is provided to have contact with the upper surface of the semiconductor module 6. Since the guide lower surface 45 has contact with the upper surface of the semiconductor module 6, the height of the control substrate 4 can be adjusted based on the upper surface of the semiconductor module 6. Also in a case where the guide lower surface 45 is provided to have contact with the upper surface of the semiconductor module 6, the distance from the protrusion part 12 to the lower surface of the control substrate 4 can be indirectly ensured. Thus, a necessary insulating space distance can be ensured.

While the embodiments etc. have been described in detail, the above embodiments are not restrictive. Various modifications and replacements can be added to the above embodiments without departing from the scope of claims.

In the above embodiments described in the present specification, material properties, materials, dimensions, shapes, relative arrangement relations, or conditions for implementation, for example, for the respective constituent elements may be described; however, these represent an exemplification in all aspects, and are not limited to the above description. Accordingly, it is understood that numerous unexemplified modification examples can be devised within the scope of each embodiment. For example, involved are a case where an optional constituent element is modified, added, or omitted and further, a case where at least one of the constituent elements of at least one of the embodiments is extracted and then combined with constituent elements of the other embodiment.

The aspects of the present disclosure are collectively described hereinafter as appendixes.

### (Appendix 1)

A semiconductor device, comprising:
a base plate;
a semiconductor module including a control terminal and provided to an upper surface of the base plate;
a control substrate which is provided on an upper side of the semiconductor module and the control terminal is connected to; and
a terminal guide,
the terminal guide including:
   a passing hole through which the control terminal passes;
a guide upper surface provided to face a lower surface of the control substrate, at least a part of the guide upper surface having contact with the lower surface of the control substrate;
a guide lower surface, at least a part of which is disposed in a position of an upper surface of the semiconductor module or below the position of the upper surface of the semiconductor module; and
a body part connecting the guide upper surface and the guide lower surface.

### (Appendix 2)

The semiconductor device according to Appendix 1, wherein
the control terminal includes a protrusion part protruding in a direction parallel to the upper surface of the base plate, a standing part standing on an upper side of the base plate, and a bending part connecting the protrusion part and the standing part, and
the guide lower surface has contact with the protrusion part.

### (Appendix 3)

The semiconductor device according to Appendix 2, wherein
the guide lower surface includes a first lower surface and a second lower surface,
the first lower surface has contact with the protrusion part, and
the second lower surface has contact with the base plate.

### (Appendix 4)

The semiconductor device according to Appendix 1, wherein
the guide lower surface has contact with the upper surface of the base plate.

### (Appendix 5)

The semiconductor device according to Appendix 1, wherein
the guide lower surface has contact with the upper surface of the semiconductor module.

### (Appendix 6)

The semiconductor device according to any one of Appendixes 1 to 5, wherein
the semiconductor module includes the plurality of terminals,
the terminal guide includes the plurality of passing holes, and
the plurality of control terminals pass through the plurality of passing holes, respectively.

### (Appendix 7)

The semiconductor device according to any one of Appendixes 1 to 6, wherein
the terminal guide is provided to be divided in a direction parallel to the control terminal at a surface including the passing hole.

### (Appendix 8)

The semiconductor device according to any one of Appendixes 1 to 7, further comprising
a plurality of semiconductor modules, wherein
the terminal guide covers the control terminal protruding from a side surface provided in the same direction in respective side surfaces of the plurality of semiconductor modules.

### (Appendix 9)

The semiconductor device according to any one of Appendixes 1 to 8, wherein
the terminal guide includes a first terminal guide part covering a control terminal protruding from one side surface of the semiconductor module, a second terminal guide part covering a control terminal protruding from another side surface located on a side opposite to the one side surface, and a relay part connecting the first terminal guide part and the second terminal guide part.

### (Appendix 10)

The semiconductor device according to Appendix 9, wherein
the relay part includes a third lower surface, and
the third lower surface has contact with the upper surface of the semiconductor module.

### (Appendix 11)

The semiconductor device according to Appendix 1, wherein
the terminal guide covers a control terminal provided to the upper surface of the semiconductor module.

### (Appendix 12)

The semiconductor device according to any one of Appendixes 1 to 11, wherein
the passing hole has a shape that a diameter on a side of the base plate is larger than a diameter on a side of the control substrate.

While the disclosure has been shown and described in detail, the foregoing description is in all aspects illustrative and not restrictive. It is therefore understood that numerous modifications and variations can be devised.

What is claimed is:

1. A semiconductor device, comprising:
a base plate;
a semiconductor module including a control terminal and provided to an upper surface of the base plate;
a control substrate which is provided on an upper side of the semiconductor module and the control terminal is connected to; and
a terminal guide,
the terminal guide including:
a passing hole through which the control terminal passes;
a guide upper surface provided to face a lower surface of the control substrate, at least a part of the guide upper surface having contact with the lower surface of the control substrate;
a guide lower surface, at least a part of which is disposed in a position of an upper surface of the semiconductor module or below the position of the upper surface of the semiconductor module; and
a body part connecting the guide upper surface and the guide lower surface.

2. The semiconductor device according to claim 1, wherein
the control terminal includes a protrusion part protruding in a direction parallel to the upper surface of the base plate, a standing part standing on an upper side of the base plate, and a bending part connecting the protrusion part and the standing part, and
the guide lower surface has contact with the protrusion part.

3. The semiconductor device according to claim 2, wherein
the guide lower surface includes a first lower surface and a second lower surface,
the first lower surface has contact with the protrusion part, and
the second lower surface has contact with the base plate.

4. The semiconductor device according to claim 1, wherein
the guide lower surface has contact with the upper surface of the base plate.

5. The semiconductor device according to claim 1, wherein
the guide lower surface has contact with the upper surface of the semiconductor module.

6. The semiconductor device according to claim 1, wherein
the control terminal includes a plurality of control terminals,
the passing hole includes a plurality of passing holes, and
the plurality of control terminals pass through corresponding passing holes in the plurality of passing holes, respectively.

7. The semiconductor device according to claim 1, wherein
the terminal guide is provided to be divided in a direction parallel to the control terminal at a surface including the passing hole.

8. The semiconductor device according to claim 1, wherein
the semiconductor module includes a plurality of semiconductor modules, and
the terminal guide covers the control terminal protruding from a side surface provided in a same direction in respective side surfaces of the plurality of semiconductor modules.

9. The semiconductor device according to claim 1, wherein
the control terminal includes a first type control terminal and a second type control terminal,
the first type control terminal protrudes from one side surface of the semiconductor module,
the second type control terminal protrudes from another side surface of the semiconductor module,
the another side surface is a side surface located on a side opposite to the one side surface, and
the terminal guide includes a first terminal guide part covering the first type control terminal, a second terminal guide part covering the second type control terminal, and a relay part connecting the first terminal guide part and the second terminal guide part.

10. The semiconductor device according to claim 9, wherein
the relay part includes a third lower surface, and
the third lower surface has contact with the upper surface of the semiconductor module.

11. The semiconductor device according to claim 1, wherein
the terminal guide covers the control terminal provided to the upper surface of the semiconductor module.

12. The semiconductor device according to claim 1, wherein
the passing hole has a shape that a diameter on a side of the base plate is larger than a diameter on a side of the control substrate.
